(19) United States
(12) Patent Application Publication
(10) Pub. No.: US 2004/0065889 A1
(43) Pub. Date: Apr. 8, 2004

(54) Semiconductor wafer, semiconductor device, and methods for fabricating the same

(75) Inventors: Tetsuzo Ueda, Osaka (JP); Masahiro Ishida, Osaka (JP)

Correspondence Address: Jack Q. Lever, Jr., McDERMOTT, WILL & EMERY, 600 Thirteenth Street, N.W., Washington, DC, 20005-3096, US

(73) Assignee: Matsushita Electric Industrial Co., Ltd.

(21) Appl. No.: 10/457,362

(22) Filed: Jun. 10, 2003

(30) Foreign Application Priority Data
Oct. 6, 2002 (JP) 2002-168779

(51) Int. Cl. H01L 29/04

(52) U.S. Cl. 257/82

(57) ABSTRACT

First, a semiconductor film made of gallium nitride with a thickness of about 5 μm is deposited on a substrate made of sapphire. Subsequently, a surface of the substrate opposite to the semiconductor film is irradiated with, e.g., a third harmonic of a YAG laser with a wavelength of 355 nm. As a result of the laser beam irradiation, the laser beam is absorbed in the region of the semiconductor film adjacent the interface with the substrate and the gallium nitride in contact with the substrate is thermally decomposed by heat resulting from the absorbed laser beam so that a precipitation layer containing metal gallium is formed at the interface between the semiconductor film and the substrate.

### BACKGROUND OF THE INVENTION

The present invention relates to a semiconductor wafer which is applicable to a short-wavelength light-emitting diode device, a short-wavelength semiconductor laser device, a high-speed electronic device, or the like, to a semiconductor device, and to methods for fabricating the same.

By virtue of its relatively large forbidden band width at room temperature, a group III-V nitride semiconductor represented by a general formula B_{z}AlₓGa_{1-x-y-z}In_{y}N_{1-v-w}AsᵥP_{w} (where x, y, z, v, and w satisfy 0≦x≦1, 0≦y≦1, 0≦z≦1, 0≦x+y+z≦1, 0≦v≦1, 0≦w≦1, 0≦v+w≦1) (generally denoted as BAIGaInNAsP and hereinafter referred to as a GaN-based semiconductor) is expected to have a wide range of applications to a light-emitting device such as a visible light-emitting diode device which outputs blue light or green light or a short-wavelength semiconductor laser element, to a transistor operable in a high-temperature environment, or to a high-power transistor capable of high-speed operation. For example, the forbidden band width of gallium nitride (GaN) is as large as 3.4 eV at room temperature. Of the light-emitting devices, the light-emitting diode device and the semiconductor laser device have already been commercialized. The light-emitting diode device has been developed diversely for display purpose and also developed for illumination purpose as a white LED. The semiconductor laser device has been developed vigorously for an application to an optical disc device capable of operating a high-density and high-capacity optical disc.

Although the GaN-based semiconductor is considered to be highly promising, it has a difficulty associated with the formation of a material. Since it is difficult to form a substrate made of GaN, a direct fabrication process as has been performed to a substrate made of silicon (Si) or gallium arsenide (GaAs) cannot be performed to the substrate of GaN. In addition, an epitaxial layer made of the same material as composing the substrate cannot be grown on the substrate so that heteroepitaxial growth which uses different materials to compose the substrate and the epitaxial layer is performed normally.

Although it has been difficult to perform even crystal growth, the quality of a GaN-based semiconductor crystal has been improved remarkably due to the great advancement of crystal growth technology centering around MOCVD (Metal Organic Chemical Vapor Deposition), with the result that the foregoing light-emitting device has been manufactured on an industrial scale.

A GaN-based semiconductor that has been used most widely and exhibits a most excellent device characteristics is one grown on a substrate made of sapphire. The crystal structure of sapphire is in a hexagonal system, similarly to a GaN-based semiconductor, and is thermally extremely stable so that it is suitable for the crystal growth of a GaN-based semiconductor which requires a high temperature of 1000° C. or more.

Conventional Embodiment 1

Referring to FIG. 9, a description will be given to a structure of a semiconductor laser device using a GaN-based semiconductor as a first conventional embodiment and to a fabrication method therefor.

As shown in FIG. 9, an n-type AlGaN layer 102, an active layer 103 made of GaInN, and a p-type AlGaN layer 104 are deposited successively by, e.g., MOCVD on a principal surface of a substrate 101 made of sapphire. The active layer 103 includes a quantum well structure. Each of the n-type AlGaN layer 102 and the p-type AlGaN layer 104 includes a cladding layer for confining light generated in the active layer 103 and an optical guide layer.

Subsequently, dry etching using chlorine gas is performed with respect to the p-type AlGaN layer 104 to selectively form a ridge portion 104a serving as a waveguide therein. Then, etching for exposing the n-type AlGaN layer 102 on both sides of the ridge portion 104a is further performed with respect to the p-type AlGaN layer 104, the active layer 103, and the n-type AlGaN layer 102.

Subsequently, an n-side electrode 105 made of Ti/Al is formed on the exposed n-type AlGaN layer 102, while a p-side electrode 106 made of Ni/Au is formed on the ridge portion 104a of the p-type AlGaN layer 104. Thereafter, the surface of the substrate 101 opposite to the n-type AlGaN layer 102 is polished such that the substrate 101 is thinned and a cavity is further formed by cleavage, whereby a semiconductor laser chip is fabricated.

A laser structure using a GaN-based semiconductor is described in detail in a paper such as: S. Nakamura et al., Japanese Journal of Applied Physics Vol.35, 1996, L74.

Conventional Embodiment 2

Referring to FIG. 10, a description will be given next to a structure of a field-effect transistor using a GaN-based semiconductor as a second conventional embodiment and to a fabrication method therefor.

As shown in FIG. 10, an undoped GaN layer 107 and an n-type AlGaN layer 108 are formed successively by, e.g., MOCVD on a principal surface of a substrate 101 made of sapphire.

Then, dry etching using chlorine gas is performed with respect to the n-type AlGaN layer 108 and to an upper portion of the undoped GaN layer 107 to form an isolation region.

Then, a source electrode 110 and a drain electrode 111 each made of, e.g., Ti/Al and a gate electrode 109 made of, e.g., Pt/Au are formed on the n-type AlGaN layer 108. Thereafter, the surface of the substrate 101 opposite to the undoped GaN layer 107 is polished such that the substrate 101 is thinned and dicing is further performed, whereby a transistor chip is fabricated.

A field-effect transistor using a GaN-based semiconductor is described in detail in a paper such as: U.K. Mishra et al., IEEE Trans Electron Device, Vol. 46, 1998, p.756.

In each of the semiconductor devices according to the first and second conventional embodiments, however, the substrate 101 is warped to have an upwardly protruding surface after epitaxial growth, as shown in FIGS. 9 and 10. This is because sapphire composing the substrate 101 and a GaN-based semiconductor have different thermal expansion coefficients so that warping occurs when the substrate 101 is cooled to a room temperature after crystal growth performed at a high temperature of about 1000° C.

Specifically, the degree of warping of the substrate 101 can be calculated by calculating respective forces and moments acting on the epitaxial growth layer and the substrate 101 such that they are balanced. If a calculation expression for obtaining the degree of warping considering only thermal expansion coefficients, which has been proposed by Olsen et al. (G. H. Olsen et al., Journal of Applied Physics Vol. 48, 1997, p.2453) is used for the GaN-based semiconductor layer grown on the substrate 101 made of sapphire, warping as large as 1/R=0.31 m⁻¹ (R: radius of curvature) occurs at a sample measuring one centimeter square on the assumption that the respective thermal expansion coefficients of sapphire and GaN are 7.5×10⁻⁶/° C. and 5.45×10⁻⁶/° C. The occurrence of warping is described also in a paper: T. Kozawa et al., Journal of Applied Physics, Vol. 77, 1995, p.4388. Since the substrate 101 undergoes warping after the formation of the epitaxial growth layer, the problem is encountered that a uniform resist size (pattern size) cannot be realized across an entire surface of a substrate (wafer) with a relatively large area in forming the stripe portion (ridge portion) of a laser structure in the epitaxial growth layer or in a photolithographic step for forming the gate electrode of a transistor structure. In a processing apparatus in which a wafer is transported by vacuum suction, the problem is encountered that the transportation of the wafer cannot be performed reliably since the wafer formed with the epitaxial growth layer is unplanar.

As a result, the stripe width of the ridge portion and the gate length of the gate electrode vary greatly across the surface of the wafer so that the production yield of the device lowers. It is therefore difficult to scale up a processible wafer to a size of 5.1 cm (equal to 2 inch) or more.

Even after the wafer is processed to a chip size, dice bonding is difficult since the surface of the chip is also unplanar even after processing. Another problem is encountered that contact with a mounting material is unsatisfactory even after dice bonding is performed and therefore uniform heat radiation is not obtained.

As described above, the substrate is normally thinned till the thickness thereof becomes 100 μm or less before it is formed into a chip. However, the degree of warping is aggravated by thinning the substrate 101 so that the warping presents a serious problem during chip assembly.

### SUMMARY OF THE INVENTION

In view of the foregoing problems, it is therefore an object of the present invention to reduce the degree of warping of a single-crystal substrate formed with a semiconductor film significantly and reliably.

To attain the object, the present invention provides a semiconductor wafer having a substrate made of a single crystal and a semiconductor film formed thereon with a precipitation layer resulting from the decomposition of a part of the semiconductor film and the precipitation of a constituent element of the semiconductor film.

Specifically, a semiconductor wafer according to the present invention comprises: a semiconductor film formed on a substrate made of a single crystal; and a precipitation layer formed in contact relation with the semiconductor film, the precipitation layer being made of a constituent element of the semiconductor film that has been precipitated as a result of decomposition of a part of the semiconductor film.

In the semiconductor wafer according to the present invention, the precipitation layer resulting from the part of the semiconductor film and from the precipitation of the constituent element thereof reduces a stress occurring between the substrate and the semiconductor film so that the warping of the substrate and the semiconductor film is prevented. If an epitaxial layer is formed on the wafer, therefore, pattern transfer in a photolithographic step and in-plane uniformity in a heat treatment step, e.g., are improved so that a high production yield is achieved.

In the semiconductor wafer according to the present invention, the semiconductor film is preferably made of a group III-V compound semiconductor containing nitrogen as a group V element. In the arrangement, if the group III-V compound semiconductor is decomposed, nitrogen as the constituent element rapidly leaves the semiconductor film so that only group III metal remains between the substrate and the semiconductor film. Since the group III metal is relatively soft, the stress occurring between the substrate and the semiconductor film can be reduced.

In the semiconductor wafer according to the present invention, the precipitation layer preferably contains metal gallium.

In the semiconductor wafer according to the present invention, the precipitation layer is preferably made of a compound containing gallium and oxygen.

In the semiconductor wafer according to the present invention, the substrate is preferably made of any one of sapphire, magnesium oxide, lithium gallium oxide, lithium aluminum oxide, and a mixed crystal of lithium gallium oxide and lithium aluminum oxide.

A method for fabricating a semiconductor wafer according to the present invention comprises the steps of: forming a semiconductor film on a substrate made of a single crystal; and irradiating a surface of the substrate opposite to the semiconductor film with irradiation light having a wavelength transmitted by the substrate and absorbed by the semiconductor film to decompose a part of the semiconductor film.

In the method for fabricating a semiconductor wafer according to the present invention, the part of the semiconductor film is decomposed by irradiating the surface of the substrate opposite to the semiconductor film with the irradiating beam. This allows the formation of the precipitation layer resulting from the precipitation of the constituent element of the semiconductor film and reliable fabrication of the semiconductor wafer according to the present invention.

In the method for fabricating a semiconductor wafer according to the present invention, the irradiation light is preferably a laser beam oscillating pulsatively. The arrangement significantly allows a significant increase in the output power of the irradiating beam and facilitates the thermal decomposition of the semiconductor film.

In the method for fabricating a semiconductor wafer according to the present invention, the irradiation light is preferably an emission line of a mercury lamp.

In the method for fabricating a semiconductor wafer according to the present invention, the irradiation is preferably performed while scanning the surface of the substrate with the irradiation light.

In the method for fabricating a semiconductor wafer according to the present invention, the irradiation is preferably performed while heating the substrate with the irradiation light.

In the method for fabricating a semiconductor wafer according to the present invention, the substrate is preferably made of any one of sapphire, magnesium oxide, lithium gallium oxide, lithium aluminum oxide, and a mixed crystal of lithium gallium oxide and lithium aluminum oxide. If the semiconductor film is made of a group III-V nitride, each of crystals of sapphire or the like has a forbidden band width larger than the forbidden band width of the group III-V nitride semiconductor and has light permeability with respect to a light beam absorbed by the group III-V nitride semiconductor so that the semiconductor film is decomposed efficiently.

A semiconductor device according to the present invention comprises: a semiconductor film formed on a substrate made of a single crystal; and a precipitation layer formed in contact relation with the semiconductor film, the precipitation layer being made of a constituent element of the semiconductor film that has been precipitated as a result of decomposition of a part of the semiconductor film.

In the semiconductor device according to the present invention, the precipitation layer formed in contact with the semiconductor film and made of the constituent element of the semiconductor film precipitated as a result of the decomposition thereof reduces the substrate and the semiconductor film so that the warping of the substrate and the semiconductor film is prevented. This improves, e.g., pattern transfer in a photolithographic step and in-plane uniformity in a heat treatment step and thereby achieves a high production yield.

In the semiconductor device according to the present invention, the semiconductor film is preferably made of a group III-V compound semiconductor containing nitrogen as a group V element.

In the semiconductor device according to the present invention, the precipitation layer preferably contains metal gallium.

In the semiconductor device according to the present invention, the precipitation layer is preferably made of a compound containing gallium and oxygen.

In the semiconductor device according to the present invention, the substrate is preferably made of any one of sapphire, magnesium oxide, lithium gallium oxide, lithium aluminum oxide, and a mixed crystal of lithium gallium oxide and lithium aluminum oxide.

In the semiconductor device according to the present invention, the semiconductor film preferably has a stepped portion in an upper part thereof. In the arrangement, if the stepped portions are formed as opposing protrusions, they can be used as a ridge-shaped waveguide if the semiconductor device is, e.g., a semiconductor laser element. If the semiconductor device is a field effect transistor, the protrusions can be used as an isolation.

In the semiconductor device according to the present invention, the semiconductor film preferably has, in an upper part thereof, a protrusion composed of two stepped portions opposing along a surface of the substrate and a distance between side surfaces of the protrusion is 2 μm or less. If the protrusions are applied to the waveguide of the semiconductor laser device, the width of the waveguide is reduced so that the occurrence of a high-order mode is suppressed in a short-wavelength laser device using a laser beam with a relatively short wavelength. As a result, the waveguide characteristic of the laser device is improved so that the optical output power is increased and the device characteristic is improved. Even when the protrusions are applied to the isolation of a transistor, the isolation width is reduced so that the chip size is further reduced.

Preferably, the semiconductor device according to the present invention further comprises: a Schottky electrode forming a junction with an upper surface of the semiconductor film.

In this case, a size of the junction of the Schottky electrode is preferably 1 μm or less.

In the semiconductor device according to the present invention, the semiconductor film is preferably a multilayer structure composed of at least two semiconductor layers of opposite conductivity types.

In this case, the multilayer structure preferably composes a light-emitting diode, a semiconductor laser diode, a field-effect transistor, or a bipolar transistor.

In this case, the multilayer structure preferably includes a quantum well structure.

A first method for fabricating a semiconductor device according to the present invention comprises the steps of: (a) forming a semiconductor film on a substrate made of a single crystal; and (b) irradiating a surface of the substrate opposite to the semiconductor film with irradiation light having a wavelength transmitted by the substrate and absorbed by the semiconductor film to decompose a part of the semiconductor film.

In accordance with the first method for fabricating a semiconductor device, the part of the semiconductor film is decomposed by irradiating the surface of the substrate opposite to the semiconductor film so that the precipitation layer resulting from the precipitation of the constituent element of the semiconductor film is formed. The precipitation layer reduces a stress occurring between the substrate and the semiconductor film so that the warping of the substrate and the semiconductor film is prevented.

In the first method for fabricating a semiconductor device, the semiconductor film is preferably made of a group III-V compound semiconductor containing nitrogen as a group V element.

The first method for fabricating a semiconductor device further comprises the steps of: (c) between the steps (a) and (b), bonding a film-like holding member made of a material different from a material composing the semiconductor film onto the semiconductor film; and (d) after the step (b), removing the holding member from the semiconductor film. The arrangement suppresses the formation of a crack in the semiconductor film in the process in which the stress on the semiconductor film is reduced by the decomposition of the semiconductor film. Consequently, the formation of the crack is suppressed even if the area of the substrate is increased and a semiconductor device with reduced warping can be fabricated.

In the semiconductor device according to the present invention, the irradiation light is preferably a laser beam oscillating pulsatively.

In the semiconductor device according to the present invention, the irradiation light is preferably an emission line of a mercury lamp.

In the semiconductor device according to the present invention, the irradiation is preferably performed while scanning the surface of the substrate with the irradiation light.

In the semiconductor device according to the present invention, the irradiation is preferably performed while heating the substrate with the irradiation light.

In the semiconductor device according to the present invention, the substrate is preferably made of any one of sapphire, magnesium oxide, lithium gallium oxide, lithium aluminum oxide, and a mixed crystal of lithium gallium oxide and lithium aluminum oxide.

The first method for fabricating a semiconductor device further comprises, after the step (b): a lithographic step, an etching step, a thermal treatment step, or a dicing step performed with respect to the semiconductor film. In the arrangement, the degree of warping of the substrate in, e.g., a photolithographic step is extremely low. Consequently, a pattern having a uniform size across the substrate can be formed even if a substrate having a relatively large area is used.

A second method for fabricating a semiconductor device according to the present invention comprises the steps of: (a) forming an underlying film on a substrate made of a single crystal; (b) irradiating a surface of the substrate opposite to the underlying film with irradiation light having a wavelength transmitted by the substrate and absorbed by the underlying film to decompose a part of the underlying film; and (c) forming a semiconductor film on the underlying film having the part thereof decomposed.

In accordance with the second method for fabricating a semiconductor device, the part of the underlying film formed on the substrate is decomposed and then the semiconductor film is formed on the underlying film so that the semiconductor film is formed with the underlying film loosely bonded to the substrate. This reduces the stress occurring in the semiconductor film during the growth thereof and allows the formation of a semiconductor film with an excellent crystalline property which is free from the influence of the different thermal expansion coefficients of the substrate and the semiconductor film and from the influence of a lattice mismatch between the substrate and the semiconductor film.

### BRIEF DESCRIPTION OF THE DRAWINGS

FIG. 1 is a structural cross-sectional view of a semiconductor wafer according to a first embodiment of the present invention;

FIGS. 2A and 2B show the semiconductor device according to the first embodiment, of which FIG. 2A is a plan photograph thereof and FIG. 2B is a transmission electron microscopic photograph of a cross section including the interface between the semiconductor wafer and a semiconductor film;

FIG. 3A is a graph showing the curvatures of the semiconductor wafer according to the first embodiment before and after the irradiation of the semiconductor wafer with a laser beam;

FIG. 3B is a view showing an interference fringe obtained as a result of measuring the degree of warping of the wafer after the laser beam irradiation;

FIG. 3C is a view showing an interference fringe obtained as a result of measuring the degree of warping of the wafer before laser beam irradiation;

FIG. 4 is a structural cross-sectional view of a semiconductor wafer according to a variation of the first embodiment;

FIG. 5 is a structural cross-sectional view of a semiconductor device according to a second embodiment of the present invention;

FIGS. 6A to 6E are structural cross-sectional views illustrating the individual process steps of a method for fabricating the semiconductor device according to the second embodiment;

FIG. 7 is a structural cross-sectional view of a semiconductor device according to a third embodiment of the present invention;

FIGS. 8A to 8E are structural cross-sectional views illustrating the individual process steps of a method for fabricating the semiconductor device according to the third embodiment;

FIG. 9 is a structural cross-sectional view of a semiconductor laser device according to a first conventional embodiment; and

FIG. 10 is a structural cross-sectional view of a field-effect transistor according to a second conventional embodiment.

### Detailed Description Of The Invention

Embodiment 1

A first embodiment of the present invention will be described with reference to the drawings.

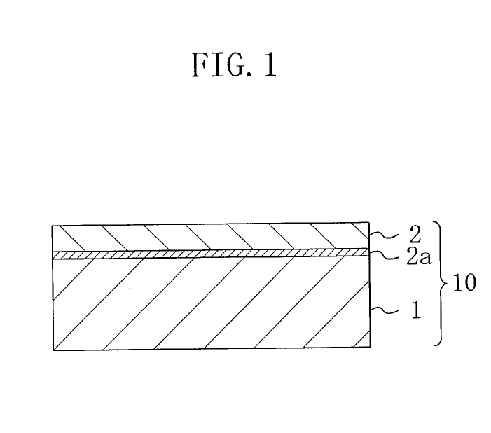

FIG. 1 shows a cross-sectional structure of a semiconductor wafer according to the first embodiment.

As shown in FIG. 1, the semiconductor wafer 10 according to the first embodiment is composed of: a substrate 1 made of sapphire; a semiconductor film 2 made of gallium nitride (GaN) with a thickness of about 5 μm; and a precipitation layer 2a containing metal gallium (Ga) precipitated at the portion of the semiconductor film 2 in contact with the substrate 1 as a result of thermal decomposition of a part of the semiconductor film 2.

A description will be given herein below to a method for fabricating the semiconductor wafer 10 thus constituted.

First, the semiconductor film 2 made of GaN with a thickness of about 5 μm is grown on a principal surface of the substrate 1 made of sapphire (single-crystal Al₂O₃) by, e.g., MOCVD (Metal Organic Chemical Vapor Deposition). For a raw material gas as a group III source, trimethylgallium (TMGa:Ga(CH₃)₃) is used. For a raw material gas as a group V source, ammonia (NH₃) is used. The raw material gases are caused to react with each other at a temperature of about 1050° C.

When the wafer 10 formed with the semiconductor film 2 is cooled to a room temperature, the wafer 10 is warped to protrude upward due to the different thermal expansion coefficients of gallium nitride and sapphire, though it is not depicted. The surface of the substrate 1 of the warped wafer 10 opposite to the semiconductor film 2 is irradiated with, e.g., the third harmonic beam of a YAG (Yttrium-Aluminum-Garnet) laser with a wavelength of 355 nm. The laser beam used for irradiation is absorbed in the region of the semiconductor film 2 in contact with the substrate 1. Gallium nitride in contact with the substrate 1 is thermally decomposed by heat resulting from the absorbed laser beam so that the precipitation layer 2a containing metal gallium is formed at the interface between the semiconductor film 2 and the substrate 1. Consequently, a stress received by the semiconductor film 2 from the substrate 1 is reduced so that the degree of the warping of the wafer 10 is reduced significantly. Preferably, the irradiation with the laser beam is performed pulsatively since a higher output of the laser beam facilitates the thermal decomposition of the semiconductor film 2.

Thus, when the group III-V compound semiconductor containing nitrogen (N) is decomposed, nitrogen as a constituent element rapidly leaves the semiconductor film so that the precipitation layer 2a containing group III metal remains between the substrate 1 and the semiconductor film 2. Since the precipitation layer 2a containing the group III metal is relatively soft, a stress occurring between the substrate 1 and the semiconductor film 2 is reduced by the precipitation layer 2a. If the precipitation layer 2a contains metal gallium, in particular, the stress occurring between the substrate 1 and the semiconductor film 2 can further be reduced since metal gallium is a liquid or an extremely soft solid even at room temperature.

The laser beam source is not limited to the third harmonic of the YAG laser. It is also possible to employ an excimer laser using KrF or ArF, which indicates a gas mixture contained in an excimer laser system. For example, KrF is a gas mixture of krypton and fluorine and ArF is a gas mixture of argon and fluorine. It is also possible to use an emission line of a mercury (Hg) lamp with a wavelength of 365 nm. If the emission line of the mercury lamp is used, the spot size can be increased compared with the case where the laser beam is used so that the beam irradiation time is reduced and a throughput in the irradiation step is increased. The, irradiation may also be performed while heating the substrate 1 to about 500° C. with the laser beam. This allows the semiconductor film 2 to be thermally decomposed while reducing the stress resulting from the different thermal expansion coefficients of the substrate 1 and the semiconductor film 2 so that a crack is prevented from occurring in the semiconductor film 2.

The following is the result of an experiment performed by the present inventors.

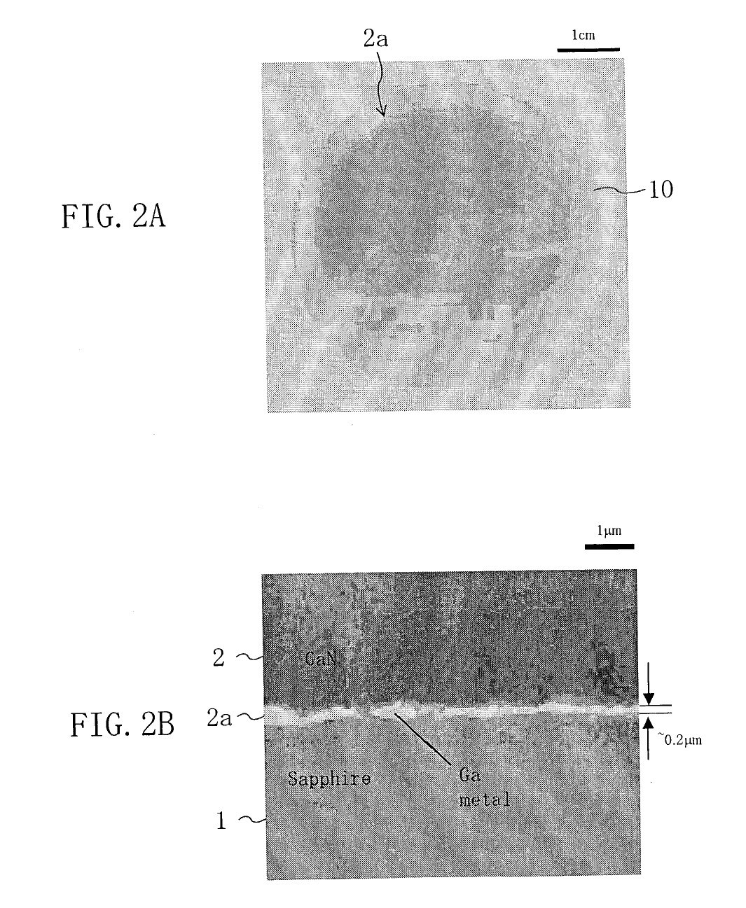

FIG. 2A is a plan photograph showing the precipitation layer 2a formed and FIG. 2B is a transmission electron microscopic photograph of a cross section including the precipitation layer 2a of the wafer 10. From FIG. 2A, it can be seen that, as a result of irradiating the entire surface of the semiconductor film 2 with the laser beam when the substrate 1 having a diameter of 5.1 cm is used, the precipitation layer 2a (the dark portion in the drawing) containing metal gallium is formed within the wafer 10. From FIG. 2B, it can be seen that the precipitation layer 2a (the light portion in the drawing) containing metal gallium is formed at the interface between the substrate 1 and the semiconductor film 2 made of GaN.

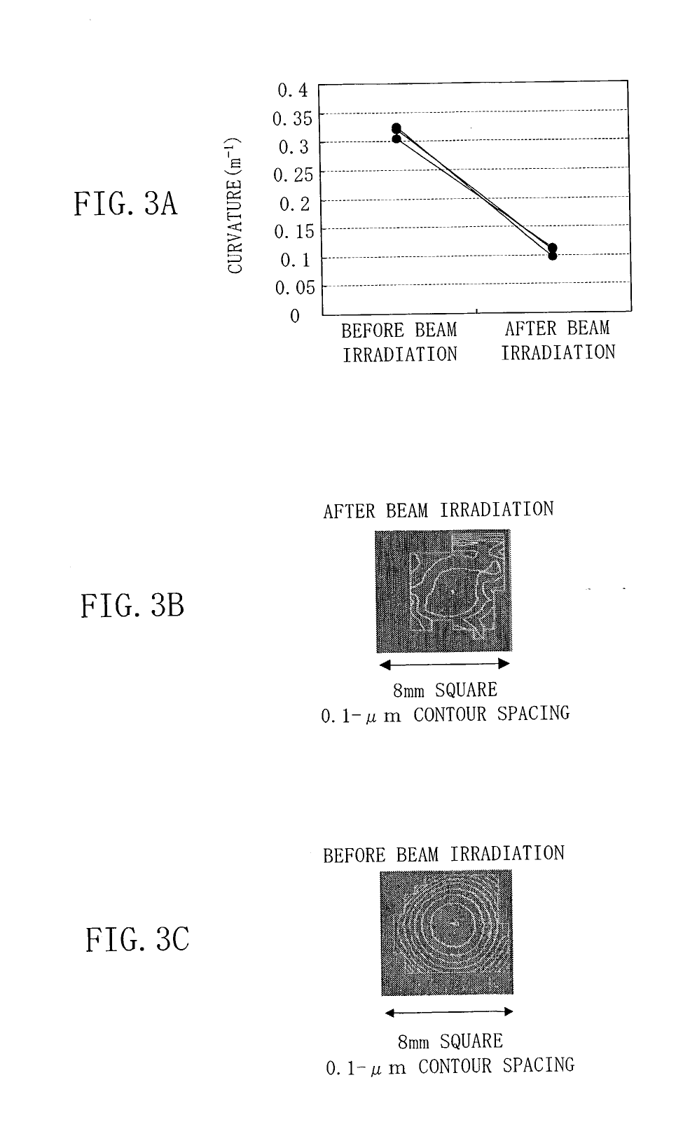

FIG. 3A shows the curvatures of the wafer 10 before and after irradiating the wafer 10 with a laser beam. As shown in FIG. 3A, the curvature of the wafer 10 before the laser beam irradiation is in the range of about 0.31 m⁻¹ to 0.33 m⁻¹. By contrast, it will be understood that the curvature of the wafer 10 after the laser beam irradiation has been reduced significantly to the range of about 0.09 m⁻¹ to 0.12 m⁻¹. The theoretical value of the curvature of the wafer 10 before the laser beam irradiation is 0.257 m⁻¹.

As shown in FIG. 3B, the density of an interference fringe measured by an interferometer after the laser beam irradiation is also reduced obviously to a level lower than the density of the interference fringe before the laser beam irradiation shown in FIG. 3C.

It is also possible to adhere, before the laser beam irradiation, a film-like holding member made of, e.g., a polymer material to the upper surface of the semiconductor film 2 and remove the holding member after the laser beam irradiation. By thus adhering the holding member to the upper surface of the semiconductor film 2, the stress placed on the semiconductor film 2 as a result of partial decomposition of the semiconductor film 2 caused by the laser beam irradiation is reduced rapidly and a crack is thereby prevented from occurring in the semiconductor film 2.

After the formation of the semiconductor wafer 10 according to the first embodiment, an epitaxial layer is formed preferably on the wafer 10 by using the formed wafer 10 as a new substrate. In the arrangement, if a semiconductor process such as photolithography is performed with respect to the epitaxial layer, a uniform pattern size is realized across the entire surface of the wafer 10 in the photolithographic step even if the area of the wafer 10 is relatively large. In the step which particularly requires vacuum suction to transport the wafer 10 having a relatively large diameter in a stepper or the like, the transportation of the warped wafer 10 cannot be performed, as described above. However, since the warping of the semiconductor wafer 10 according to the first embodiment has significantly been reduced, the transportation of the wafer 10 by vacuum suction can be performed so that existing process facilities are usable.

In the step of, e.g., RIE (Reactive Ion Etching), annealing, or the like which requires heating and cooling using a heat sink, uniform heating and cooling can be performed even if the wafer has a relatively large diameter.

If a device structure such as a semiconductor laser structure is to be formed by epitaxial growth on the semiconductor wafer 10, the device structure can be grown while protecting the semiconductor film 2 as an underlying layer from being affected by a lattice mismatch occurring between the substrate 1 and itself or by the different thermal expansion coefficient of the substrate 1, since the semiconductor film 2 is provided with the precipitation layer 2a interposed between the semiconductor layer 2 and the substrate 1.

Thus, since the method for fabricating a semiconductor wafer according to the first embodiment forms the precipitation layer 2a containing metal gallium at the interface between the substrate 1 and the semiconductor film 2 grown epitaxially thereon, the semiconductor wafer 10 with reduced warping can be fabricated even if the area of the wafer 10 is relatively large.

Even though the diameter of the semiconductor wafer 10 is relatively large, if an epitaxial layer having a desired device structure is formed on the semiconductor film 2 of the semiconductor wafer 10 and then a process such as photolithography is performed with respect to the formed epitaxial layer, the uniformity and reproducibility of the ridge stripe width in the case of forming a semiconductor laser device and those of the gate length in the case of forming a field effect transistor are improved across the entire surface of the wafer so that a high production yield is achievable.

Although sapphire has been used for the substrate 1, it is not limited thereto. Any material such as magnesium oxide (MgO), lithium gallium oxide (LiGaO₂), lithium aluminum oxide (LiAlO₂), or lithium gallium aluminum oxide (LiGaₓAl₁₋ₓO₂) (where x satisfies 0<x<1) may be used provided that it does not substantially absorb the irradiation beam absorbed by a GaN-based semiconductor.

If the group III-V compound semiconductor containing nitrogen is decomposed, a compound layer containing a group III element in a large amount may be formed between the substrate 1 and the semiconductor film 2 instead of the precipitation layer 2a. If zinc oxide (ZnO) is used for the substrate 1 instead of sapphire, a compound layer consisting of a group III element and oxygen resulting from the decomposition of zinc oxide may be formed. If gallium is taken as an example of the group III element, Ga₂O₃, GaOₓ (where x represents the composition of oxygen), or GaOₓN_{y} (where x represents the composition of oxygen and y represents the composition of nitrogen) as gallium oxide may be formed. However, the stress occurring between the substrate 1 and the semiconductor film 2 is reduced by the compound layer containing a group III element in a large amount since the compound layer containing such a group III element in a large amount is formed after the laser beam irradiation and becomes structurally fragile due to a hollow portion or the like resulting from partial evaporation or leave of the constituent element thereof under the radiation of the laser beam.

The compound layer containing a group III element in a large amount may also be a layer made of group III metal and a compound containing a group III element in a large amount. For example, it may be a layer containing metal gallium (Ga), GaOₓ and GaOₓN_{y}. In this case, the stress occurring between the substrate 1 and the semiconductor film 2 is reduced by the layer containing the group III metal and the group III element in a large amount.

The material composing the semiconductor film 2 is not limited to a GaN-based semiconductor. The semiconductor film 2 may be made of a group III-V nitride semiconductor containing boron (B) as a group III element or a group III-V nitride semiconductor layer containing arsenide (As) or phosphorus (P) as a group V element.

It is also possible to provide a light absorbing layer made of InGaN or ZnO which has a forbidden band width smaller than that of GaN. The arrangement accelerates the absorption of the irradiation beam by the light absorbing layer so that the light absorbing layer is decomposed even with a low-output irradiation beam.

Variation of Embodiment 1

A variation of the first embodiment of the present invention will be described with reference to the drawings.

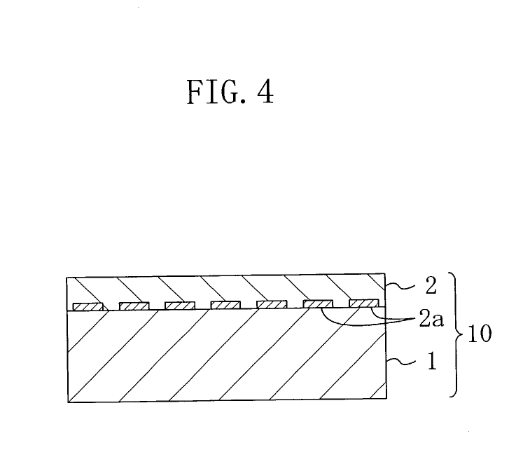

FIG. 4 shows a cross-sectional structure of a semiconductor wafer according to the variation of the first embodiment. The description of the components shown in FIG. 4 which are the same as those shown in FIG. 1 will be omitted by retaining the same reference numerals.

As shown in FIG. 4, the precipitation layer 2a containing metal gallium in the semiconductor wafer 10 according to the present variation is not formed over the entire interface with the substrate 1 but formed discretely (at intervals).

A specific formation method is as follows: When the surface of the substrate 1 opposite to the semiconductor film 2 is irradiated with, e.g., the third harmonic of a YAG laser, scanning is not performed continuously as in the first embodiment but irradiation is performed incontinuously across the surface of the substrate 1.

It is also possible to set, by using the non-uniformity of the intensity of a laser beam outputted pulsatively, the pulse width and output value of the laser beam such that decomposition occurs at the interface between the semiconductor film 2 and the substrate 1 only during a period during which the output value is high and that the precipitation layer 2a containing metal gallium is formed selectively at the interface between the semiconductor film 2 and the substrate 1.

In the present variation also, the stress received by the semiconductor film 1 from the substrate 1 is reduced and the degree of the warping of the wafer 10 is reduced satisfactorily since the precipitation layer 2a containing metal gallium is formed discretely, i.e., selectively at the interface between the semiconductor film 2 and the substrate 1.

If a device structure such as a semiconductor laser structure is further grown epitaxially on the semiconductor film 2 of the semiconductor wafer 10, the epitaxial growth layer grows with the precipitation layer 2a interposed between the substrate 1 and itself This allows the formation of the device structure free from the influence of a lattice mismatch occurring between the substrate 1 and the epitaxial growth layer and the influence of the different thermal expansion coefficient of the substrate 1.

Embodiment 2

A second embodiment of the present invention will be described herein below with reference to the drawings.

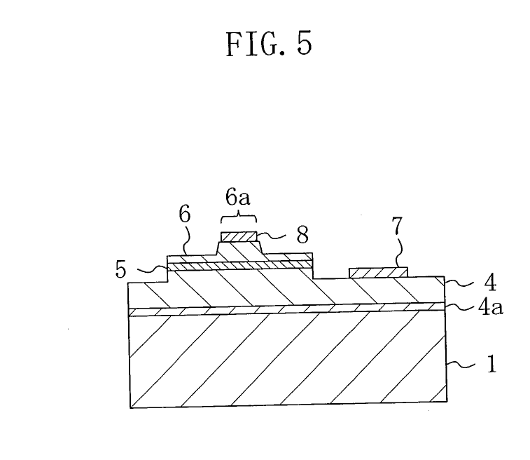

FIG. 5 shows a cross-sectional structure of a semiconductor laser device as a semiconductor device according to the second embodiment.

As shown in FIG. 5, the semiconductor laser device according to the second embodiment has: a first cladding layer 4 made of n-type aluminum gallium nitride (AlGaN); an active layer 5 made of undoped indium gallium nitride (InGaN); and a second cladding layer 6 made of p-type aluminum gallium nitride (AlGaN) which are formed successively on a substrate 1 made of, e.g., sapphire.

At the interface between the first cladding layer 4 and the substrate 1, a precipitation layer 4a containing metal gallium resulting from the decomposition of the region of the first cladding layer 4 in contact with the substrate 1 and the adjacent region thereof and from the precipitation of the constituent element of the first cladding layer 4 is formed.

The upper portion of the second cladding layer 6 is formed with a ridge-shaped waveguide 6a and the regions of the first cladding layer 4 located on both sides of the waveguide 6a are exposed. An n-side electrode 7 composed of a multilayer film of titanium (Ti) and aluminum (Al) is formed on the exposed portions of the first cladding layer 4, while a p-side electrode 8 composed of a multilayer film of nickel (Ni) and gold (Au) is formed on the waveguide 6a of the second cladding layer 6.

A description will be given herein below to a method for fabricating the semiconductor laser thus constituted.

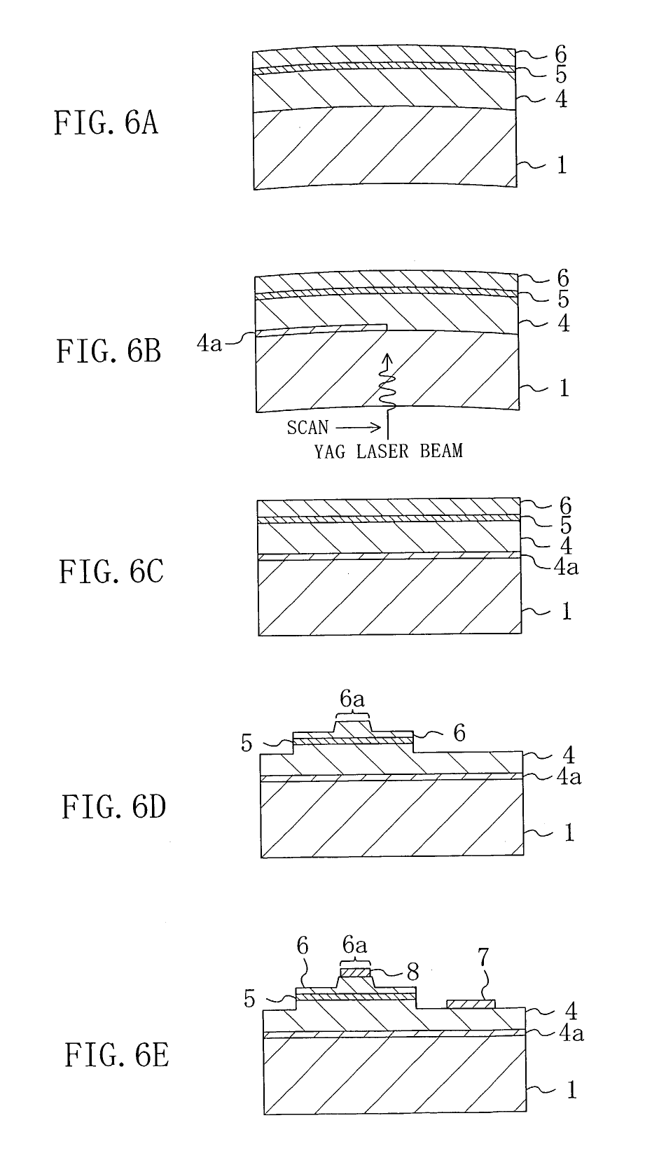

FIGS. 6A to 6E are cross-sectional views illustrating the individual process steps of the method for fabricating the semiconductor laser device according to the second embodiment.

First, as shown in FIG. 6A, the first cladding layer 4 made of n-type AlGaN, the active layer 5 made of undoped InGaN, and the second cladding layer 6 made of p-type AlGaN are deposited successively by, e.g., MOCVD on a principal surface of the substrate 1 having its temperature controlled to about 1020° C. Hereinafter, the first cladding layer 4, the active layer 5, and the second cladding layer 6 will be referred to as an epitaxial layer.

As shown in Table 1, the semiconductor laser device is preferably constituted such that a buffer layer and a first contact layer are provided between the substrate 1 and the first cladding layer 4, the active layer 5 includes a quantum well structure, respective optical guide layers are provided between the active layer 5 and the first cladding layer 4 and between the active layer 5 and the second cladding layer 6, and a second contact layer is further provided on the second cladding layer 6.

TABLE 1

| Name | | | Composition | Thickness |
|---|---|---|---|---|
| 2nd Contact Layer | | | p-GaN | 0.2 μm |
| 2nd Cladding layer | | | p-Al_{0.07}Ga_{0.93}N | 0.4 μm |
| 2nd Optional Guide Layer | | | p-GaN | 0.1 μm |
| | Active | Barrier Layers | In_{0.05}Ga_{0.95}N | 5.0 nm |
| | Layer | Well Layers | In_{0.2}Ga_{0.8}N | 2.5 nm |

| | | |
|---|---|---|
| 1st Optical Guide Layer | n-GaN | 0.1 μm |
| 1st Cladding layer | n-Al_{0.07}Ga_{0.93}N | 0.4 μm |
| 1st Contact Layer | n-GaN | 3 μm |
| Buffer Layer | GaN | 30 nm |
| Substrate | Sapphire | — |

Note: Active layer includes three barrier layers and three well layers which are alternately stacked.

As is well known, the buffer layer formed on the substrate 1, which is shown in Table 1, reduces a lattice mismatch between the substrate 1 and the epitaxial layer grown on the buffer layer, such as the first contact layer if the substrate is set to a relatively low temperature of, e.g., 550° C. Each of the cladding layers 4 and 6 confines the recombination light of carriers generated in the active layer 5. Each of the optical guide layers improves the efficiency with which the recombination light is confined. As an n-type dopant, silicon (Si) obtained from, e.g., silane (SiH₄) is used. As a p-type dopant, magnesium (Mg) obtained from, e.g., biscyclopentadienylmagnesium (Cp₂Mg) is used.

If the substrate 1 completed with the grown epitaxial layer is cooled to a room temperature, the substrate 1 including the epitaxial layer is warped to protrude upward due to the different thermal expansion coefficients of the epitaxial layer made of the GaN-based semiconductor and sapphire, as shown in FIG. 6A, in the same manner as in the first embodiment.

To reduce the degree of warping, the surface of the warped substrate 1 opposite to the epitaxial layer is then irradiated with, e.g., the high-output and pulsative third harmonic of a YAG laser such that it scans across the entire surface, as shown in FIG. 6B. As a result of the laser beam irradiation, the laser beam is absorbed in the region of the first cladding layer 4 (or the buffer layer in the case where the buffer layer is provided) adjacent the interface with the substrate 1 and the GaN-based semiconductor in contact with the substrate 1 is thermally decomposed by heat resulting from the absorbed laser beam so that the precipitation layer 4a containing metal gallium is formed at the interface between the first cladding layer 4 and the substrate 1. Since the precipitation layer 4a containing metal gallium reduces the stress received by the epitaxial layer from the substrate 1, the degree of warping of the substrate 1 and the epitaxial layer is reduced significantly, as shown in FIG. 6C. The laser beam source used here may be an excimer laser beam using KrF or ArF. Alternatively, an emission line of a mercury lamp with a wavelength of 365 nm may also be used instead of the laser beam source. It is also possible to perform irradiation with the laser beam or the emission line, while heating the substrate 1 to about 500° C. The precipitation layer 4a need not necessarily be formed over the entire interface between the substrate 1 and the epitaxial layer. The precipitation layer 4a may also be formed discretely in the same manner as in the second embodiment.

Next, as shown in FIG. 6D, dry etching using chlorine gas as etching gas is performed with respect to the second cladding layer 6 of the epitaxial layer of which the degree of warping has been reduced by the laser beam irradiation, thereby selectively forming a ridge portion 6a serving as a waveguide with a width of about 1.7 μm in the upper portion of the second cladding layer 6. Subsequently, dry etching is performed with respect to the second cladding layer 6, the active layer 5, and the first cladding layer 4, thereby forming a laser structure including the ridge portion 6a and in which the first cladding layer 4 is exposed.

Next, as shown in FIG. 6E, the n-side electrode 7 made of titanium and aluminum is formed by, e.g., vapor deposition on the exposed first cladding layer 4, while the p-side electrode 8 made of nickel and gold is formed on the ridge portion 6a of the second cladding layer 6. If a second contact layer made of p-type GaN is provided on the second cladding layer 6, the p-side electrode 8 is formed on the second contact layer since the second contact layer is included in the upper portion of the ridge portion 6a. If a first contact layer made of n-type GaN is similarly provided between the substrate 1 and the first cladding layer 4, etching for forming the laser structure is performed till the first contact layer is exposed and the n-side electrode 7 is formed on the exposed first contact layer.

Thus, the second embodiment has formed the epitaxial layer on the substrate 1, irradiated the region of the epitaxial layer in contact with the substrate 1 with the laser beam, and thereby formed the precipitation layer 4a containing metal gallium in the region so that the degree of warping of the substrate 1 and the epitaxial layer is reduced. This allows a pattern used for photolithography (mask size) which determines the width (stripe width) of the ridge portion 6a to have a uniform size across the substrate surface.

Since the substrate 1 is hardly warped in the subsequent dry etching step for forming the ridge portion 6a, the substrate 1 and the epitaxial layer are cooled uniformly so that the depth of etching is also uniform across the surface of the substrate. If the semiconductor laser device is processed into a chip in the step of polishing the back surface of the substrate 1 subsequent to the dry etching step, in the cleaving step, and in the dicing step, the warping of the substrate 1 has substantially disappeared so that assembly including dice bonding becomes easy and an excellent contact is provided between the chip and a mounting material. As a result, heat radiation from the device becomes uniform.

It is to be noted that the stepped portions of the first cladding layer 4 formed by etching for providing the region to be formed with the n-side electrode 7 may also be used for the isolation of the ridge-shaped waveguide structure. If the distance between the respective side surfaces of the opposing stepped portions is adjusted to 2 μm or less, the occurrence of a high-order mode in a short-wavelength laser device can be suppressed so that the wave-guiding characteristic of the laser device is improved.

It is also possible to use the semiconductor wafer according to either of the first embodiment and the variation thereof, use the semiconductor film 2 thereof as an underlying film, and form a semiconductor laser structure on the underlying film.

Alternatively, an epitaxial layer including a light-emitting diode structure instead of the semiconductor laser structure may also be formed on the substrate 1 or on the semiconductor film 2.

In a typical example of the light emitting diode structure, a first cladding layer made of GaN with a thickness of about 4 μm, a multiple quantum well active layer including three well layers each made of undoped indium gallium nitride (In_{0.2}Ga_{0.8}N) and three barrier layers each made of undoped gallium nitride (GaN), which are alternately stacked, and having a total thickness of 30 nm, and a second cladding layer made of GaN with a thickness of about 0.2 μm are formed successively on a substrate 1. The light-emitting diode device having this structure emits blue light a wavelength of about 450 nm.

Embodiment 3

A third embodiment of the present invention will be described herein below with reference to the drawings.

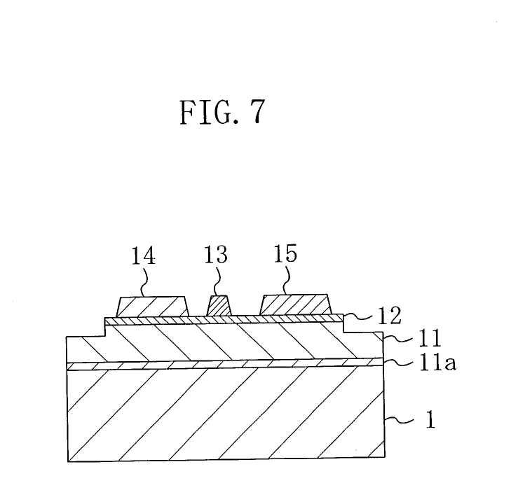

FIG. 7 shows a cross-sectional structure of a field effect transistor as a semiconductor device according to the third embodiment.

As shown in FIG. 7, the field effect transistor according to the third embodiment has a first semiconductor layer 11 made of undoped gallium nitride (GaN) and a second semiconductor layer 12 made of n-type aluminum gallium nitride (AlGaN) formed successively on a substrate 1 made of, e.g., sapphire.

At the interface between the first semiconductor layer 11 and the substrate 1, a precipitation layer 11a resulting from the decomposition of the region of the first semiconductor layer 11 in contact with the substrate 1 and the adjacent region thereof and containing metal gallium resulting from the precipitation of the constituent element of the first semiconductor layer 11 is formed.

A gate electrode 13 made of platinum (Pt) and gold (Au) is formed on the second semiconductor layer 12. A source electrode 14 and a drain electrode 15 each made of titanium (Ti) and aluminum (Al) are formed on both sides of the gate electrode 13.

A description will be given herein below to a method for fabricating the field effect transistor thus constituted.

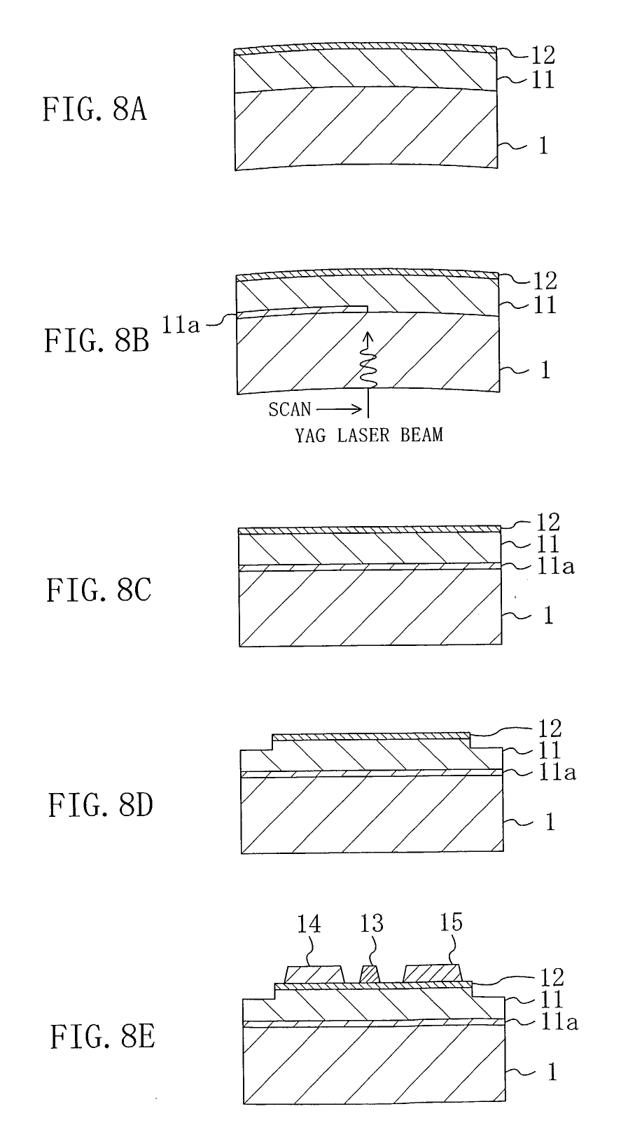

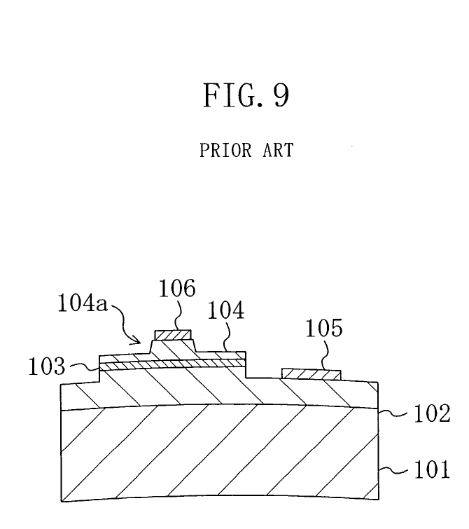

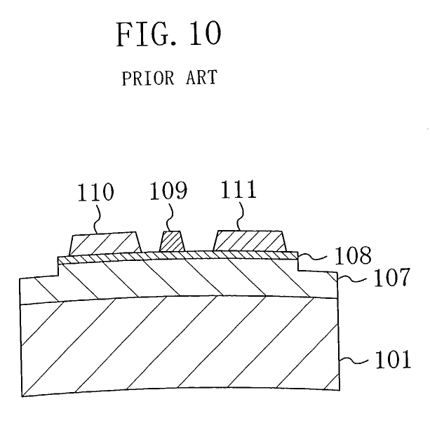

FIGS. 8A to 8E are cross-sectional views illustrating the individual process steps of the method for fabricating the field effect transistor according to the third embodiment.

First, as shown in FIG. 8A, the first semiconductor layer 11 made of undoped GaN and the second semiconductor layer 12 made of n-type AlGaN are deposited successively by, e.g., MOCVD on a principal surface of the substrate 1 made of sapphire and having its temperature controlled to about 1020° C. The total thickness of the epitaxial layer including the first and second semiconductor layers 11 and 12 is 2 μm to 3 μm.

If the substrate 1 completed with the grown semiconductor layers 11 and 12 is cooled to a room temperature, the substrate 1 including the semiconductor layers 11 and 12 is warped to protrude upward due to the different thermal expansion coefficients of the GaN-based semiconductor layer and sapphire as shown in FIG. 8A, in the same manner as in the first embodiment.

To reduce the degree of warping, the surface of the warped substrate 1 opposite to the first semiconductor layer 11 is then irradiated with, e.g., the high-output and pulsative third harmonic of a YAG laser such that it scans across the entire surface, as shown in FIG. 8B. As a result of the laser beam irradiation, the laser beam is absorbed in the region of the first semiconductor layer 11 in contact with the substrate 1 and the adjacent region thereof and the first semiconductor layer 11 in contact with the substrate 1 is thermally decomposed by heat resulting from the absorbed laser beam so that the precipitation layer 11a containing metal gallium is formed at the interface between the first semiconductor layer 11 and the substrate 1. Since the stress received by the semiconductor layers 11 and 12 from the substrate 1 is reduced, the degree of warping of the substrate 1 and the semiconductor layers 11 and 12 is reduced significantly, as shown in FIG. 8C. The laser beam source used here may also be an excimer laser beam using KrF or ArF. Alternatively, an emission line of a mercury lamp with a wavelength of 365 nm may also be used. It is also possible to perform irradiation with the laser beam or the emission line, while heating the substrate 1 to about 500° C.

Next, as shown in FIG. 8D, dry etching using chlorine gas as etching gas is performed with respect to the first semiconductor layer 11 of which the degree of warping has been reduced by the laser beam irradiation so that a mesa isolation portion as stepped portions for isolation is formed in the upper portion of the first semiconductor layer 11 such that the width of the device region becomes about 2.0 μm.

Next, as shown in FIG. 8E, the source and drain electrodes 14 and 15 each made of titanium and aluminum are formed by a lift-off process on the both end portions of the second semiconductor layer 12 isolated by the mesa isolation portion. Subsequently, the gate electrode 13 made of platinum and gold is formed by a lift-off process on the region of the second semiconductor layer 12 located between the source and drain electrodes 15. The lift-off process used herein is a technique which deposits a metal film over a mask pattern composed of a resist having an opening in a specified pattern or the like, removes the deposited metal film together with the mask pattern, and thereby leaves the metal film in the portion corresponding to the opening. The order in which the source and drain electrodes 14 and 15 and the gate electrode 13 are formed is not fixed.

To improve the RF characteristic of the transistor, it is essential to reduce the gate length of the gate electrode 13. Preferably, the gate length is set to 1 μm or less and more preferably to 0.5 μm or less.

Subsequently, the substrate 1 is thinned by polishing the back surface thereof and dicing is performed for the chip, whereby the transistor chip is formed.

Thus, the third embodiment has formed the first and second semiconductor layers 11 and 12 on the substrate 1, irradiated, with a laser beam, the region of the first semiconductor layer 11 in contact with the substrate 1, and thereby formed the precipitation layer 11a containing metal gallium in the region so that the degree of the warping of the substrate 1 and the semiconductor layers 11 and 12 is reduced. This allows a pattern used for photolithography (mask size) which determines the gate length of the gate electrode 13 to have a uniform size across the substrate surface.

Since the warping of the substrate 1 has substantially disappeared when the substrate 1 is processed into a chip in the subsequent steps of polishing the back surface of the substrate 1, cleaving the substrate 1, and dicing the substrate 1, assembly including dice bonding becomes easy and an excellent contact is provided between the chip and a bonding material. As a result, heat radiation from the device becomes uniform. It is more effective to apply the field effect transistor with a reduced degree of warping to a high-power device having a large chip size.

Since the width of the device region sandwiched between the mesa isolation portions has been set to about 2.0 μm, the chip size can further be reduced.

In the third embodiment also, it is possible to use the semiconductor wafer according to either of the first embodiment and the variation thereof, use the semiconductor film 2 thereof as an underlying film, and form a transistor structure on the underlying film.

The field effect transistor need not necessarily be constructed to have the two semiconductor layers 11 and 12. The transistor structure is not limited to the field effect transistor. A bipolar transistor may also be used.

In each of the first to third embodiments, the plane orientation of the principal surface of the substrate 1 is not particularly limited. In the case of using, e.g., sapphire, it is also possible to provide a typical (0001) plane or a plane orientation slightly deviated from the typical plane (off orientation).

The method for the crystal growth of the epitaxial layer containing a plurality of GaN-based semiconductors is not limited to MOCVD. It is also possible to use molecular beam epitaxy (MBE) or hydride vapor phase epitaxy (HVPE). It is also possible to selectively use the foregoing three growth methods.

The epitaxial layer containing these GaN-based semiconductors may appropriately include a layer which absorbs the irradiation beam. The layer which absorbs the irradiation beam need not necessarily be in contact with the substrate 1. The composition of the layer which absorbs the irradiation beam is not limited to GaN. The composition may be any group III-V nitride semiconductor having an arbitrary composition such as, e.g., AlGa or InGaN.

It is also possible to provide a light absorbing layer composed of InGaN or ZnO which has a forbidden band width smaller than that of GaN between the substrate 1 and the device structure made of a GaN-based semiconductor. The arrangement accelerates the absorption of the irradiation beam by the light absorbing layer so that the light absorbing layer is decomposed even with a low-output irradiation beam.

Before or after the beam irradiation step, a holding substrate made of, e.g., silicon (Si) may also be bonded onto the epitaxial layer for easy handling of the substrate 1 and the epitaxial layer.

What is claimed is:

1. A semiconductor wafer comprising:
a semiconductor film formed on a substrate made of a single crystal; and
a precipitation layer formed in contact relation with the semiconductor film, the precipitation layer being made of a constituent element of the semiconductor film that has been precipitated as a result of decomposition of a part of the semiconductor film.

2. The semiconductor wafer of claim 1, wherein the semiconductor film is made of a group III-V compound semiconductor containing nitrogen as a group V element.

3. The semiconductor wafer of claim 1, wherein the precipitation layer contains metal gallium.

4. The semiconductor wafer of claim 1, wherein the precipitation layer is made of a compound containing gallium and oxygen.

5. The semiconductor wafer of claim 1, wherein the substrate is made of any one of sapphire, magnesium oxide, lithium gallium oxide, lithium aluminum oxide, and a mixed crystal of lithium gallium oxide and lithium aluminum oxide.

6. A method for fabricating a semiconductor wafer, the method comprising the steps of:
forming a semiconductor film on a substrate made of a single crystal; and
irradiating a surface of the substrate opposite to the semiconductor film with irradiation light having a wavelength transmitted by the substrate and absorbed by the semiconductor film to decompose a part of the semiconductor film.

7. The method of claim 6, wherein the irradiation light is a laser beam oscillating pulsatively.

8. The method of claim 6, wherein the irradiation light is an emission line of a mercury lamp.

9. The method of claim 6, wherein the irradiation is performed while scanning the surface of the substrate with the irradiation light.

10. The method of claim 6, wherein the irradiation is performed while heating the substrate with the irradiation light.

11. The method of claim 6, wherein the substrate is made of any one of sapphire, magnesium oxide, lithium gallium oxide, lithium aluminum oxide, and a mixed crystal of lithium gallium oxide and lithium aluminum oxide.

12. A semiconductor device comprising:
a semiconductor film formed on a substrate made of a single crystal; and
a precipitation layer formed in contact relation with the semiconductor film, the precipitation layer being made of a constituent element of the semiconductor film that has been precipitated as a result of decomposition of a part of the semiconductor film.

13. The semiconductor device of claim 12, wherein the semiconductor film is made of a group III-V compound semiconductor containing nitrogen as a group V element.

14. The semiconductor device of claim 12, wherein the precipitation layer contains metal gallium.

15. The semiconductor device of claim 12, wherein the precipitation layer is made of a compound containing gallium and oxygen.

16. The semiconductor device of claim 12, wherein the substrate is made of any one of sapphire, magnesium oxide, lithium gallium oxide, lithium aluminum oxide, and a mixed crystal of lithium gallium oxide and lithium aluminum oxide.

17. The semiconductor device of claim 12, wherein the semiconductor film has a stepped portion in an upper part thereof.

18. The semiconductor device of claim 12, wherein the semiconductor film has, in an upper part thereof, a protrusion composed of two stepped portions opposing along a surface of the substrate and a distance between side surfaces of the protrusion is 2 μm or less.

19. The semiconductor device of claim 12, further comprising:
a Schottky electrode forming a junction with an upper surface of the semiconductor film.

20. The semiconductor device of claim 19, wherein a size of the junction of the Schottky electrode is 1 μm or less.

21. The semiconductor device of claim 12, wherein the semiconductor film is a multilayer structure composed of at least two semiconductor layers of opposite conductivity types.

22. The semiconductor of claim 21, wherein the multilayer structure composes a light-emitting diode, a semiconductor laser diode, a field-effect transistor, or a bipolar transistor.

23. The semiconductor device of claim 22, wherein the multilayer structure includes a quantum well structure.

24. A method for fabricating a semiconductor device, the method comprising the steps of:
(a) forming a semiconductor film on a substrate made of a single crystal; and
(b) irradiating a surface of the substrate opposite to the semiconductor film with irradiation light having a wavelength transmitted by the substrate and absorbed by the semiconductor film to decompose a part of the semiconductor film.

25. The method of claim 24, wherein the semiconductor film is made of a group III-V compound semiconductor containing nitrogen as a group V element.

26. The method of claim 24, further comprising the steps of:
(c) between the steps (a) and (b), bonding a film-like holding member made of a material different from a material composing the semiconductor film onto the semiconductor film; and
(d) after the step (b), removing the holding member from the semiconductor film.

27. The method of claim 24, wherein the irradiation light is a laser beam oscillating pulsatively.

28. The method of claim 24, wherein the irradiation light is an emission line of a mercury lamp.

29. The method of claim 24, wherein the irradiation is performed while scanning the surface of the substrate with the irradiation light.

30. The method of claim 24, wherein the irradiation is performed while heating the substrate with the irradiation light.

31. The method of claim 24, wherein the substrate is made of any one of sapphire, magnesium oxide, lithium gallium oxide, lithium aluminum oxide, and a mixed crystal of lithium gallium oxide and lithium aluminum oxide.

32. The method of claim 24, further comprising, after the step (b):
a lithographic step, an etching step, a thermal treatment step, or a dicing step performed with respect to the semiconductor film.

33. A method for fabricating a semiconductor device, the method comprising the steps of:
(a) forming an underlying film on a substrate made of a single crystal;
(b) irradiating a surface of the substrate opposite to the underlying film with irradiation light having a wavelength transmitted by the substrate and absorbed by the underlying film to decompose a part of the underlying film; and
(c) forming a semiconductor film on the underlying film having the part thereof decomposed.
